(19) United States
(12) Patent Application Publication
(10) Pub. No.: US 2016/0251754 A1
(43) Pub. Date: Sep. 1, 2016

(54) HEATER ABNORMALITY DETECTING APPARATUS, PROCESSING LIQUID SUPPLYING APPARATUS, AND SUBSTRATE PROCESSING SYSTEM

(71) Applicant: SCREEN Holdings Co., Ltd., Kyoto (JP)

(72) Inventors: Akihiro NAKASHIMA, Kyoto (JP); Jun SAWASHIMA, Kyoto (JP); Kenji KOBAYASHI, Kyoto (JP)

(21) Appl. No.: 15/052,028

(22) Filed: Feb. 24, 2016

(30) Foreign Application Priority Data
Feb. 26, 2015 (JP) 2015-037240

(51) Int. Cl. C23C 16/02; G01N 27/00

(52) U.S. Cl. CPC C23C 16/0209; G01N 27/00

(57) ABSTRACT

A heater abnormality detecting apparatus is arranged to detect an abnormality of a heater, the heater contacting a processing liquid to heat the processing liquid and having a heating element made of metal and a coating made of resin and covering a periphery of the heating element, and the apparatus includes a grounding unit grounding the processing liquid in contact with the heater, a power supplying unit supplying power to the heating element to make the heating element generate heat, an electric current measuring unit measuring an electric current flowing through the heating element, and a tear formation detecting unit detecting formation of a tear in the coating based on a magnitude of the electric current detected by the electric current measuring unit.

### BACKGROUND OF THE INVENTION

1. Field of the Invention

The present invention relates to a heater abnormality detecting apparatus arranged to detect an abnormality of a heater, a processing liquid supplying apparatus arranged to supply a processing liquid, and a substrate processing system processing a substrate by using the processing liquid. Examples of substrates that may be processing objects include semiconductor wafers, substrates for liquid crystal displays, substrates for plasma displays, substrates for FEDs (Field Emission Displays), substrates for optical disks, substrates for magnetic disks, substrates for magneto-optical disks, substrates for photomasks, ceramic substrates, substrates for solar cells, etc.

2. Description of Related Art

In a manufacturing process for a semiconductor device or a liquid crystal display device, etc., a substrate processing system that uses a processing liquid to perform processing of a substrate, such as a semiconductor wafer or a glass substrate for a liquid crystal display, etc., is used. Such a substrate processing system includes, apart from a processing portion that applies processing to the substrate, a chemical liquid supplying unit arranged to supply a chemical liquid to the processing portion. The chemical liquid supplying apparatus supplies a chemical liquid, adjusted to a predetermined temperature, to the processing portion.

For example, a chemical liquid cabinet (chemical liquid supplying apparatus), included in a substrate processing apparatus (substrate processing system) described in Japanese Patent Application Publication No. 2010-232520, includes a chemical liquid tank storing a chemical liquid to be supplied to a processing portion, a chemical liquid circulation passage, through which the chemical liquid inside the chemical liquid tank flows, and a heater disposed at the chemical liquid circulation passage.

### SUMMARY OF THE INVENTION

Such a heater for chemical liquid heating includes a heating wire and a coating made of resin that covers the heating wire. The heater directly contacts a processing liquid (chemical liquid) flowing through a flow passage and heats the processing liquid.

However, a tear may form in the coating covering a periphery of the heating element (heating wire) due to abnormal overheating or occurrence of static electricity in the heater or due to degradation with time of the coating. In this case, metal is eluted from a portion of the heating element that is exposed by the tear in the coating and the processing liquid inside a processing liquid supplying unit (chemical liquid supplying unit) becomes contaminated with the metal. The metal-contaminated processing liquid is supplied to a processing portion from the processing liquid supplying unit and consequently, metal contamination of a substrate that is the processing object may occur.

An apparatus that detects such a tear in the coating of the heater is not provided. Therefore, it is difficult to detect such a tear in the coating. Especially when a tear in the coating is small (when a hole is formed), it is even more difficult to detect such a tear in the coating because it does not have influence on an operation state of the substrate processing system.

An object of the present invention is thus to provide a heater abnormality detecting apparatus capable of detecting, with high precision, a tear in a coating covering a periphery of a heating element.

Also, another object of the present invention is to provide a processing liquid supplying apparatus capable of supplying a processing liquid free of metal contamination.

Also, yet another object of the present invention is to provide a substrate processing system capable of applying processing to a substrate using a processing liquid while avoiding occurrence of metal contamination.

A first aspect of the present invention provides a heater abnormality detecting apparatus arranged to detect an abnormality of a heater, contacting a processing liquid to heat the processing liquid and having a heating element made of metal and a coating made of resin and covering a periphery of the heating element, the apparatus including a grounding unit grounding the processing liquid in contact with the heater, a power supplying unit supplying power to the heating element to make the heating element generate heat, an electric current measuring unit measuring an electric current flowing through the heating element, and a tear formation detecting unit detecting formation of a tear in the coating based on a magnitude of the electric current detected by the electric current measuring unit.

With the present arrangement, the processing liquid in contact with the heater is grounded. Therefore, if a tear is formed in the coating, an electric current leaks out into the chemical liquid from the heating element that is exposed due to the tear in the coating and a leakage current flows in the chemical liquid. The magnitude of the electric current flowing through the heating element thus changes in comparison to a case where a tear is not formed in the coating. The tear in the coating can thus be detected by measuring the electric current flowing through the heating element by means of the electric current measuring unit and monitoring changes in the measured electric current. A tear in the coating covering the periphery of the heating element can thereby be detected with high precision.

In the preferred embodiment of the present invention, the heater abnormality detecting apparatus according to the first aspect is such that the power supplying unit includes a first power line connected to an AC power supply and a second power line connected to the AC power supply and being different from the first power line, the heating element includes a heating wire with ends, one end of the heating wire is connected to the first power line, the other end of the heating wire is connected to the second power line, and the electric current measuring unit includes an electric current difference measuring unit measuring a difference of an electric current flowing through a first portion at the one end side of the heating wire and an electric current flowing through a second portion at the other end side of the heating wire.

With the present arrangement, an electric current flowing into the heating wire from one of either of the first and second portions flows out from the other of either of the first and second portions. The electric current flowing through the first portion and the electric current flowing through the second portion thus cancel each other out. If a tear is not formed in the coating, the difference of the electric current flowing through the first portion and the electric current flowing through the second portion is zero. On the other hand, if a tear is formed in the coating, a leakage current flows into the processing liquid and therefore the difference of the electric current flowing through the first portion and the electric current flowing through the second portion will not be zero. That is, a tear in the coating can be detected based on the difference of the electric currents not being zero. A tear in the coating can thereby be detected with even higher precision.

Also, the electric current difference measuring unit may include a clamp meter.

With the present arrangement, the electric current flowing through the heating wire is measured indirectly by measuring a magnetic field due to the electric current by means of the clamp meter. The electric current can be measured without contacting the heating wire and therefore the measurement of the electric current can be performed safely.

Also, the electric currents flowing through the first portion and the second portion may be measured collectively by the clamp meter.

With the present arrangement, the electric currents flowing through the first portion and the second portion are measured collectively by the clamp meter and therefore influence of electric current measurement error can be lessened in comparison to a case where the electric currents flowing through the first portion and the second portion are measured individually. A tear in the coating can thereby be detected with even higher precision.

Also, a second aspect of the present invention provides a processing liquid supplying apparatus arranged to supply a processing liquid to a processing portion arranged to apply processing by the processing liquid to a processing object, the processing liquid supplying apparatus including a flow passage, through which the processing liquid flows, a heater arranged to contact the processing liquid present in an interior of the flow passage and heat the processing liquid, the heater including a heating element made of metal and a coating made of resin and covering a periphery of the heating element, and a heater abnormality detecting apparatus arranged to detect an abnormality of a heater, the heater contacting a processing liquid to heat the processing liquid and having a heating element made of metal and a coating made of resin and covering a periphery of the heating element, the apparatus including, a grounding unit grounding the processing liquid in contact with the heater, a power supplying unit supplying power to the heating element to make the heating element generate heat, an electric current measuring unit measuring an electric current flowing through the heating element, and a tear formation detecting unit detecting formation of a tear in the coating based on a magnitude of the electric current detected by the electric current measuring unit.

With the present arrangement, a tear in the coating covering the periphery of the heating element can be detected with high precision and therefore metal contamination in an interior of the processing liquid supplying apparatus can be prevented in advance. Processing liquid free of metal contamination can thereby be supplied to the processing portion from the processing liquid supplying apparatus.

The flow passage may include a processing liquid tank storing the processing liquid to be supplied to the processing portion and a processing liquid piping guiding the processing liquid from the processing liquid tank to the processing portion, the heater may include a first heater immersed in the processing liquid stored in the processing liquid tank and heating the processing liquid, and the grounding unit may include a first grounding unit grounding the processing liquid stored in the processing liquid tank.

With the present arrangement, the heater is immersed in the processing liquid stored in the processing liquid tank and the processing liquid is grounded by the first grounding unit. A tear in the coating can be detected with high precision by measuring the electric current flowing through the heating element by means of the electric current measuring unit and monitoring changes in the measured electric current.

The first grounding unit may include a conductive member disposed so as to contact the processing liquid stored in the processing liquid tank and a first ground wire arranged to ground the conductive member.

With the present arrangement, the processing liquid stored in the processing liquid tank is grounded by means of the conductive member and the first ground wire. Grounding of the processing liquid stored in the processing liquid tank can thus be realized satisfactorily.

Also, the flow passage may include a processing liquid tank storing the processing liquid to be supplied to the processing portion and a processing liquid piping guiding the processing liquid from the processing liquid tank to the processing portion, the heater may include a second heater interposed in the processing liquid piping and heating the processing liquid flowing through the processing liquid piping, and the grounding unit may include a second grounding unit grounding the processing liquid flowing through the processing liquid piping.

With the present arrangement, the heater contacts the processing liquid flowing through the processing liquid piping and the processing liquid is grounded by the second grounding unit. A tear in the coating can be detected with high precision by measuring the electric current flowing through the heating wire by means of the electric current measuring unit and monitoring changes in the measured electric current.

Also, with the processing liquid piping, at least a portion connected to the second heater may be disposed as a conductive piping formed using a material having conductivity, and the second grounding unit may include a second ground wire arranged to ground the conductive piping.

With the present arrangement, the processing liquid flowing through the processing liquid piping is grounded by means of the conductive piping and the second ground wire. Grounding of the processing liquid flowing through the processing liquid piping can thus be realized satisfactorily.

Also, a third aspect of the present invention is a processing portion arranged to apply processing by a processing liquid to a processing object, and a processing liquid supplying apparatus arranged to supply a processing liquid to a processing portion arranged to apply processing by the processing liquid to a processing object, the processing liquid supplying apparatus including a flow passage, through which the processing liquid flows, a heater arranged to contact the processing liquid present in an interior of the flow passage and heat the processing liquid, the heater including a heating element made of metal and a coating made of resin and covering a periphery of the heating element, and a heater abnormality detecting apparatus arranged to detect an abnormality of a heater, the heater contacting a processing liquid to heat the processing liquid and having a heating element made of metal and a coating made of resin and covering a periphery of the heating element, the apparatus including a grounding unit grounding the processing liquid in contact with the heater, a power supplying unit supplying power to the heating element to make the heating element generate heat, an electric current measuring unit measuring an electric current flowing through the heating element, and a tear formation detecting unit detecting formation of a tear in the coating based on a magnitude of the electric current detected by the electric current measuring unit, and supplying a processing liquid, supplied from the processing liquid supplying apparatus, to a substrate inside the processing portion to process the substrate.

With the present arrangement, processing liquid free of metal contamination is supplied from the processing liquid supplying apparatus to the processing portion and therefore processing using the processing liquid can be applied to the substrate while avoiding occurrence of metal contamination.

Also, the supplying of the processing liquid from the processing liquid supplying apparatus to the substrate may be stopped when the tear formation detecting unit detects the formation of a tear in the coating.

With the present arrangement, the supplying of the processing liquid from the processing liquid supplying apparatus to the substrate is stopped when the formation of a tear in the coating is detected. The supplying of the processing liquid for which there is a possibility of metal contamination is stopped and occurrence of defective items can thus be suppressed to a minimum.

The above and yet other objects, features, and effects of the present invention shall be made clear by the following description of the preferred embodiments in reference to the attached drawings.

### BRIEF DESCRIPTION OF THE DRAWINGS

FIG. 1 is a diagram of a substrate processing system according to a first preferred embodiment of the present invention as viewed in a horizontal direction.

FIG. 2 is a diagram of the arrangement in a periphery of a chemical liquid tank included in the substrate processing system shown in FIG. 1.

FIG. 3 is a diagram of the arrangement of a heater installed in a processing liquid supplying apparatus shown in FIG. 2.

FIG. 4 is a flowchart of the flow of detection of abnormality of the heater.

FIG. 5 is a diagram of a substrate processing system according to a second preferred embodiment of the present invention as viewed in a horizontal direction.

FIG. 6 is a diagram of the arrangement in a periphery of a heating unit included in the substrate processing system shown in FIG. 5.

### DETAILED DESCRIPTION OF PREFERRED EMBODIMENTS

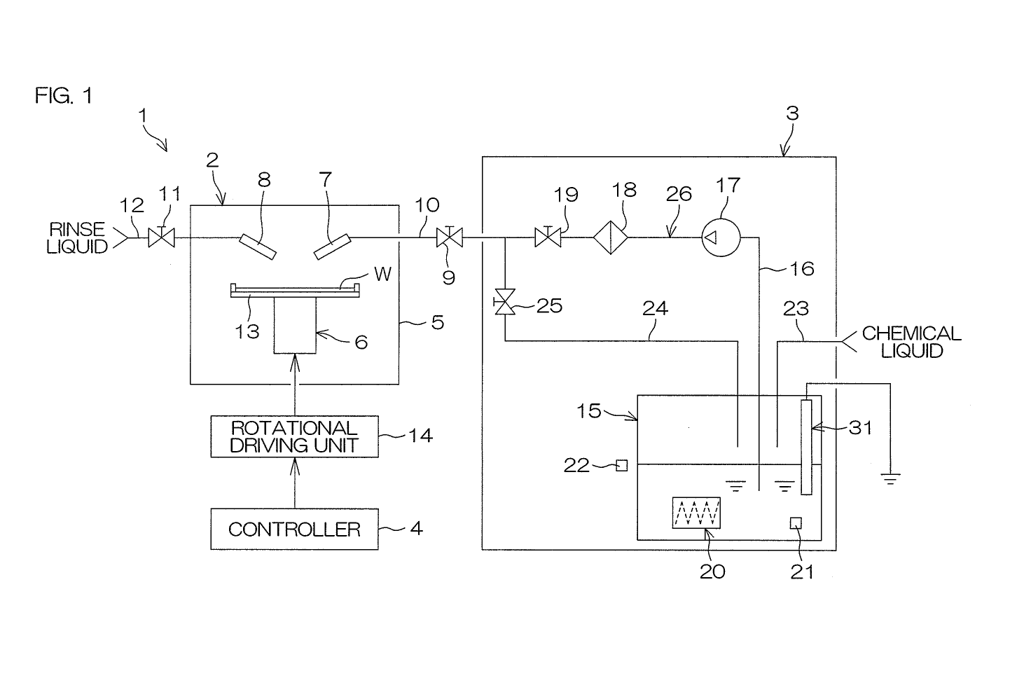

FIG. 1 is a diagram of a substrate processing system 1 according to a first preferred embodiment of the present invention as viewed in a horizontal direction. The substrate processing system 1 includes a processing unit (processing portion) 2, processing a semiconductor wafer, as an example of a substrate W, a chemical liquid supplying unit 3 as a chemical liquid supplying apparatus (processing liquid supplying apparatus) supplying a chemical liquid to the processing unit 2, and a controller 4 controlling operations of apparatuses and opening and closing of valves included in the substrate processing system 1. The controller 4 is arranged using, for example, a microcomputer. The controller 4 has a calculating unit, such as a CPU, etc., a storage unit, such as a fixed memory device, hard disk drive, etc., and an input/output unit. A program executed by the calculating unit is stored in the storage unit. The processing unit 2 and the chemical liquid supplying unit 3 may be portions of the same apparatus or may be mutually independent units (units capable of being moved mutually independently). That is, the substrate processing system 1 may include substrate processing system that includes the processing unit 2 and the chemical liquid supplying unit 3 or may include a substrate processing apparatus that includes the processing unit 2 and a chemical liquid supplying unit 3 disposed at a position separated from the substrate processing apparatus. Also, the processing unit 2 may be a single substrate processing type unit that processes the substrate W one by one or may be a batch type unit that processes a plurality of substrates W in a batch. FIG. 1 shows an example where the processing unit 2 is a single substrate processing type unit. Also, although in FIG. 1, just a single chemical liquid supplying unit 3 is illustrated, if a plurality of chemical types are to be provided, chemical liquid supplying units 3 of a number corresponding to the chemical types may be provided.

The processing unit 2 includes a box-shaped chamber 5 having an internal space, a spin chuck 6 holding a single substrate W in a horizontal orientation inside the chamber 5 and rotating the substrate W around a vertical rotational axis passing through a center of the substrate W, a chemical liquid nozzle 7 arranged to supply the chemical liquid to the substrate W held by the spin chuck 6, and rinse liquid nozzle 8 arranged to supply a rinse liquid to the substrate W held by the spin chuck 6.

As shown in FIG. 1, the chemical liquid nozzle 7 is connected to the chemical liquid supplying unit 3. The chemical liquid nozzle 7 is connected to a chemical liquid supply piping 10 in which a chemical liquid supply valve 9 is interposed. A chemical liquid of a fixed temperature within a range, for example, of 40° C. to 70° C. is supplied to the chemical liquid supply piping 10 from the chemical liquid supplying unit 3.

The chemical liquid supplied to the chemical liquid nozzle 7 is a chemical liquid that improves in processing ability by being set to a high temperature (a temperature not less than room temperature). As examples of such a chemical liquid, sulfuric acid, SC1 (ammonia-hydrogen peroxide mixture), SC2 (hydrochloric acid/hydrogen peroxide mixture), etc., can be cited.

The rinse liquid nozzle 8 is connected to a rinse liquid piping 12 in which a rinse liquid valve 11 is interposed. Pure water (deionized water), which is an example of a rinse liquid, is supplied to the rinse liquid nozzle 8. The rinse liquid supplied to the rinse liquid nozzle 8 is not restricted to pure water and may be any of carbonated water, electrolyzed ion water, hydrogen water, ozone water, and aqueous hydrochloric acid solution of dilute concentration (for example of approximately 10 to 100 ppm).

The spin chuck 6 includes a disk-shaped spin base 13 capable of rotating around the vertical axis while holding the substrate W substantially horizontally and a motor or other rotational driving unit 14 that rotates the spin base 13 around the vertical axis. Each of the chemical liquid nozzle 7 and the rinse liquid nozzle 8 may be a fixed nozzle, with which a liquid landing position of the chemical liquid or rinse liquid on the substrate W is fixed, or may be a scan nozzle, with which the liquid landing position of the chemical liquid or rinse liquid is moved in a range from the center of rotation of the substrate W to a peripheral edge of the substrate W.

When processing is to be performed on the substrate W, the controller 4 makes the spin chuck 6 rotate the substrate W around the vertical axis while holding the substrate W horizontally. In this state, the controller 4 opens the chemical liquid supply valve 9 to make the chemical liquid be discharged from the chemical liquid nozzle 7 toward an upper surface of the substrate W. The chemical liquid supplied to the substrate W spreads outward on the substrate W due to a centrifugal force due to rotation of the substrate W and is expelled from an upper surface peripheral edge portion of the substrate W to a periphery of the substrate W. The controller 4 stops the discharge of the chemical liquid from the chemical liquid nozzle 7 and thereafter opens/closes the rinse liquid valve 11 to make pure water be discharged from the rinse liquid nozzle 8 toward the upper surface of the substrate W in the rotating state. The chemical liquid on the substrate W is thereby rinsed off by the pure water. Thereafter, the controller 4 makes the spin chuck 6 rotate the substrate W at a high speed to dry the substrate W. A series of processing on the substrate W is thus performed.

The chemical liquid supplying unit 3 includes a chemical liquid tank (processing liquid tank) 15 storing the chemical liquid, a chemical liquid piping (processing liquid piping) 16 guiding the chemical liquid inside the chemical liquid tank 15 to the processing unit 2 (chemical liquid nozzle 7), a liquid feeding apparatus 17 moving the chemical liquid inside the chemical liquid tank 15 to the chemical liquid piping 16, a filter 18 filtering the chemical liquid flowing through an interior of the chemical liquid piping 16, a chemical liquid valve 19 opening/closing the chemical liquid piping 16, a first heater 20 immersed in the chemical liquid stored in the chemical liquid tank 15 and heating and performing temperature adjustment of the chemical liquid, a thermometer 21 measuring a temperature of the chemical liquid stored in the chemical liquid tank 15, a liquid volume sensor 22 monitoring a liquid volume inside the chemical liquid tank 15, and a replenishing piping 23 replenishing the chemical liquid tank 15 with fresh chemical liquid.

The liquid feeding apparatus 17 may be a pump that sucks the liquid inside the tank into the piping or may be a pressurizing piping that supplies a gas to raise gas pressure inside the tank to feed the liquid inside the tank into the piping. FIG. 1 shows an example where the liquid feeding apparatus 17 is a pump interposed in the chemical liquid piping 16.

The chemical liquid piping 16 has one end thereof connected to the chemical liquid supply piping 10 and has the other end connected to the chemical liquid tank 15. The liquid feeding apparatus 17, the filter 18, and the chemical liquid valve 19 are interposed in the chemical liquid piping 16 in that order along a chemical liquid flow direction.

The chemical liquid supplying unit 3 further includes, at a further downstream side in the chemical liquid flow direction than the chemical liquid valve 19, a return piping 24 connecting the chemical liquid piping 16 and the chemical liquid tank 15 and a return valve 25 arranged to open/close the return piping 24. A circulation passage (flow passage) 26 that circulates the chemical liquid inside the chemical liquid tank 15 is defined by the chemical liquid tank 15, the chemical liquid piping 16, and the return piping 24.

As shown in FIG. 1, when, in a state in which the liquid feeding apparatus 17 is being driven, the chemical liquid valve 19 and the return valve 25 are opened and the chemical liquid supply valve 9 is closed, the chemical liquid pumped out from the chemical liquid tank 15 passes through the filter 18, the chemical liquid valve 19, the return valve 25, and the return piping 24 and is returned to the chemical liquid tank 15. The chemical liquid inside the chemical liquid tank 15 is thereby circulated through the circulation passage 26.

When from this state, the return valve 25 is closed and the chemical liquid supply valve 9 is opened, the chemical liquid circulating through the circulation passage 26 is supplied through the chemical liquid supply valve 9 to the chemical liquid nozzle 7 and the chemical liquid is discharged from the chemical liquid nozzle 7. The chemical liquid is thereby supplied to the substrate W and the substrate W is processed using the chemical liquid.

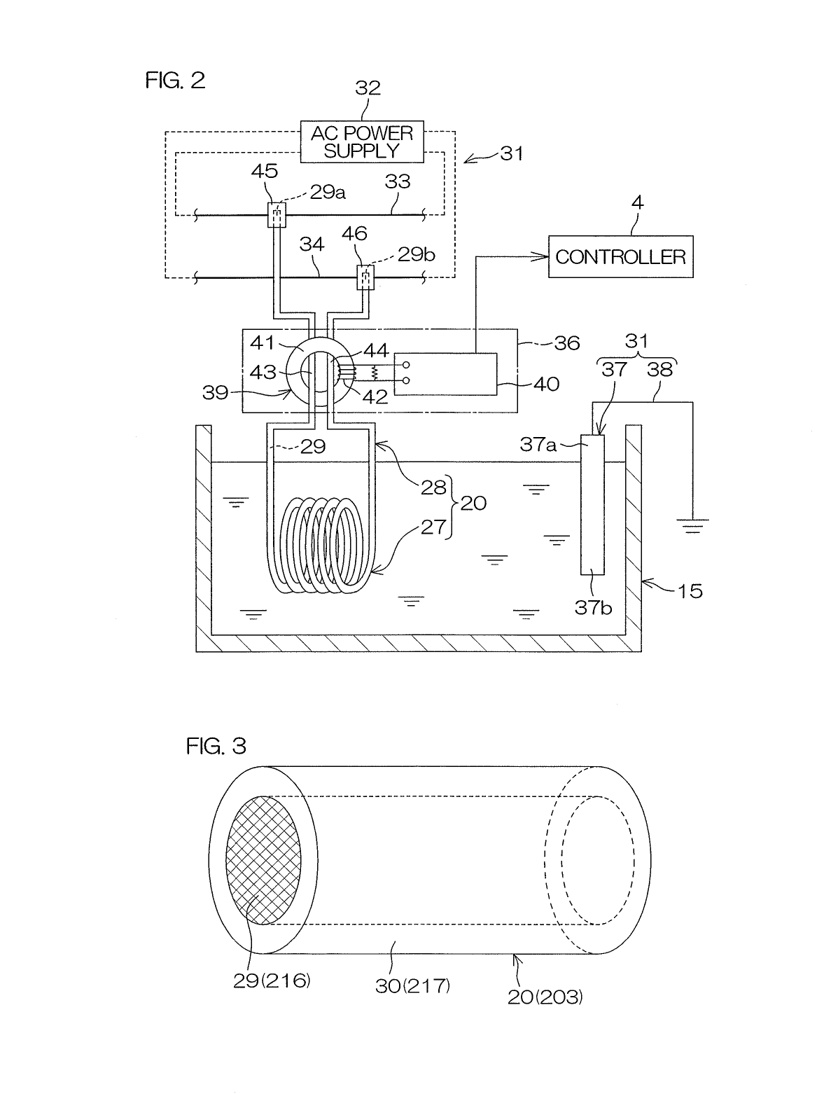

FIG. 2 is a diagram of the arrangement in a periphery of the chemical liquid tank 15. FIG. 3 is a diagram of the arrangement of the first heater 20.

The first heater 20 is a sheath heater and its overall shape constitutes a shape that includes, for example, a circular annular portion 27 with ends and a pair of rectilinear portions 28 extending upward from one end portion and another end portion of the circular annular portion 27. In FIG. 2, the rectilinear portions 28 are drawn in a bent manner for the sake of description. The entirety of the circular annular portion 27 of the first heater 20 is immersed in the chemical liquid stored in the chemical liquid tank 15.

As shown in FIG. 3, the sheath heater (first heater 20) includes a heating wire 29 and a coating 30 covering the heating wire 29. A metal is adopted as the material of the heating wire 29. As examples of such a metal, Fe, Ni, Al, etc., can be cited. Also, a synthetic resin is adopted as the material of the coating 30. As such a resin, in addition to a resin having chemical resistance, such as PTFE (polytetrafluoroethylene), PFA (perfluoro-alkylvinyl-ether-tetrafluoroethylene copolymer), etc., a resin not having chemical resistance, such as polyvinylchloride, may also be used.

The chemical liquid supplying unit 3 further includes a power supplying unit (power supplying unit) 31 supplying power to the heating wire 29 of the first heater 20 to make the heating wire 29 generate heat.

The power supplying unit 31 includes a first power line 33 arranged to be connected to an external AC power supply 32 and a second power line 34 arranged to be connected to the AC power supply 32 outside the substrate processing system 1. One end 29a of the heating wire 29 is connected via a first terminal 45 to the first power line 33 and another end 29b of the heating wire 29 is connected via a second terminal 46 to the second power line 34. By an insertion plug (not shown) of the chemical liquid supplying unit 3 (or the substrate processing system 1) being inserted into an outlet, the AC power supply 32 is connected to the first power line 33 and the second power line 34. An AC voltage is thereby applied to the heating wire 29 from the AC power supply 32.

The chemical liquid supplying unit 3 further includes a heater abnormality detecting unit that detects an abnormality of the first heater 20 disposed inside the chemical liquid tank 15. The heater abnormality detecting unit includes a first grounding unit (see FIG. 2) 35 that grounds the chemical liquid stored in the chemical liquid tank 15, an ammeter (electric current difference measuring unit, electric current measuring unit) 36 that measures an electric current flowing through the heating wire 29 of the first heater 20, and a tear formation detecting unit (realized by the controller 4) that detects the formation of a tear in the coating 30 based on a magnitude of the electric current detected by the ammeter 36.

As the ammeter 36, for example, a current transformer type clamp meter, which clamps a measurement object in its interior, is adopted. The ammeter 36 includes a sensor 39 and a calculating circuit 40 that determines an electric current value of the measurement object by calculation based on a detection output of the sensor 39. The sensor 39 has a circular annular magnetic core 41 that surrounds a measurement object and a coil 42 wound around the magnetic core 41. A first portion 43 at the one end 29a side of the heating wire 29 and a second portion 44 at the other end 29b side of the heating wire 29 are measured collectively as the object of measurement by the ammeter 36. That is, both the first portion 43 and the second portion 44 of the heating wire 29 are surrounded by the magnetic core 41 of the ammeter 36. The electric current value determined by the calculating circuit 40 is arranged to be provided to the controller 4. By the ammeter 36 constituted from the clamp meter, the electric currents flowing through the first portion 43 and the second portion 44 of the heating wire 29 are measured indirectly by measuring a magnetic field due to the electric currents. The ammeter 36 measures the electric currents without directly contacting the heating wire 29. Measurement of the electric currents is thus performed safely.

The first grounding unit 35 includes a conductive member 37, which, for example, is rod-shaped and is disposed so that a lower end 37b contacts the chemical liquid stored in the chemical liquid tank 15, and a first ground wire 38 connected to an upper end 37a of the conductive member 37 and grounding the upper end 37a. The chemical liquid stored in the chemical liquid tank 15 is grounded by the conductive member 37 and the first ground wire 38 and therefore when a tear is formed in the coating 30, an electric current leaks out into the chemical liquid from the heating wire 29 that is exposed due to the tear in the coating 30 and a leakage current flows inside the chemical liquid. The magnitude of the electric current flowing through the heating wire 29 thus changes in comparison to a case where a tear is not formed in the coating 30. By measuring the electric current of the heating wire 29 by the ammeter 36 at this point, the tear in the coating 30 covering the heating wire 29 can be detected. That is, an abnormality of the first heater 20 can be detected.

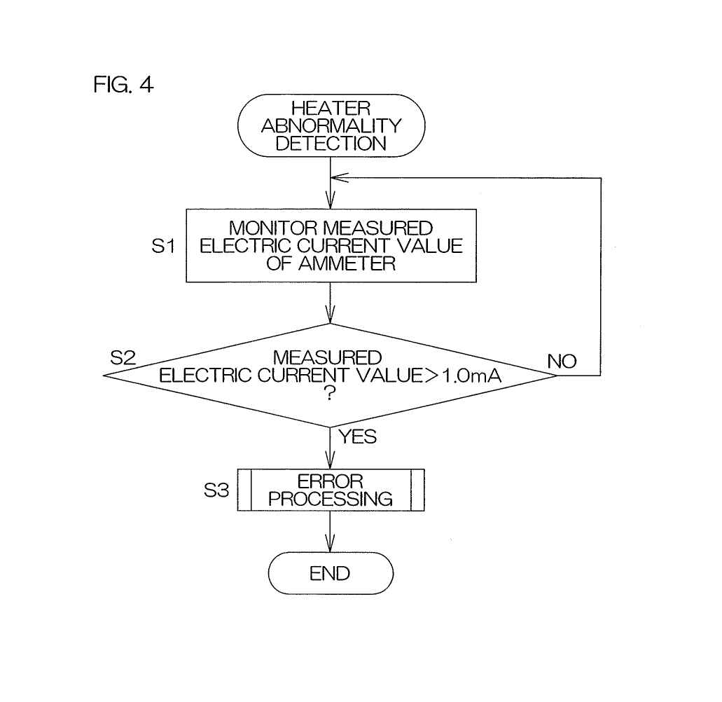

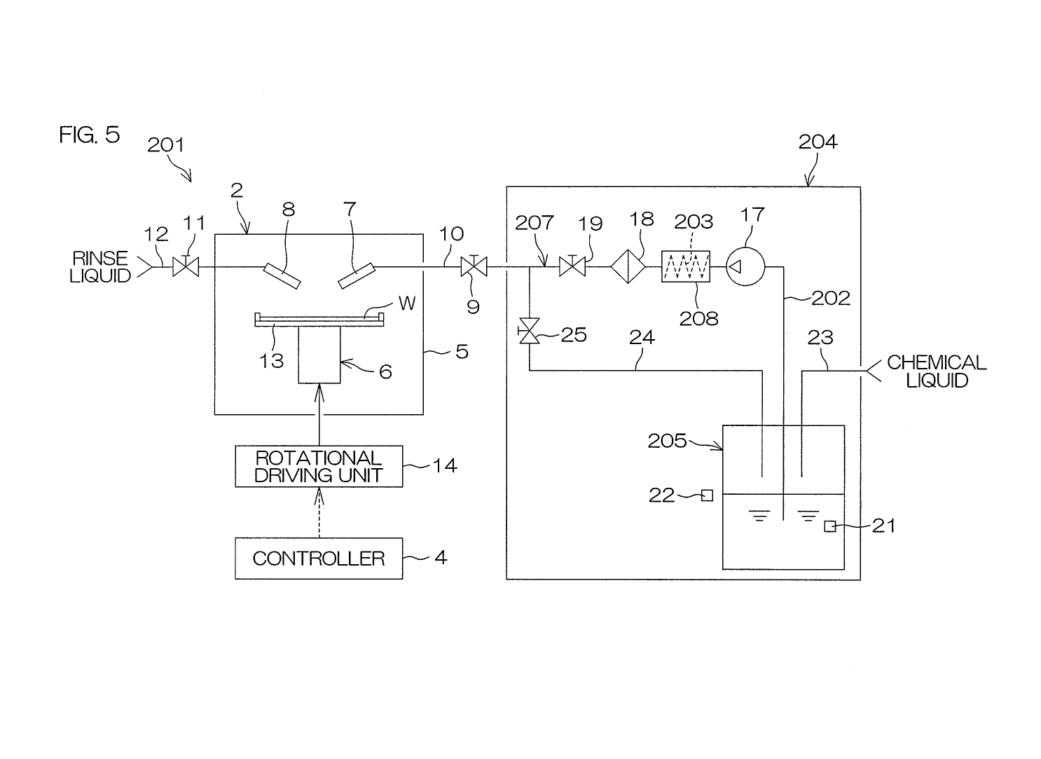

FIG. 4 is a flowchart of the flow of detection of abnormality of the first heater 20.

The controller 4 monitors the electric current value (measured electric current value) provided from the ammeter 36 (step S1). At the power supplying unit 31, the electric current flowing into the heating wire 29 from one of either of the first and second portions 43 and 44 flows out from the other of either of the first and second portions 43 and 44 and therefore the electric current flowing through the first portion 43 and the electric current flowing through the second portion 44 cancel each other out. If a tear is not formed in the coating 30, the measured value of the ammeter 36 (that is, the difference of the electric current flowing through the first portion 43 and the electric current flowing through the second portion 44) is substantially zero. On the other hand, if a tear is formed in the coating 30, a leakage current flows into the processing liquid and therefore the measured value of the ammeter 36 will not be substantially zero. In the present preferred embodiment, a threshold (of, for example, 1.0 mA) of the measured electric current value is determined in advance.

If the measured electric current value exceeds the predetermined threshold (of, for example, 1.0 mA) (YES in step S2), the controller 4 deems that a tear is formed in the coating 30 and performs an error processing (step S3). As the error processing, for example, the chemical liquid supply valve 9 is stopped. The supplying of the chemical liquid from the chemical liquid supplying unit 3 to the processing unit 2 is thereby stopped.

As described above, with the present preferred embodiment, the first heater 20 is immersed in the chemical liquid stored in the chemical liquid tank 15 and the chemical liquid is grounded via the conductive member 37 and the first ground wire 38. Therefore, when a tear forms in the coating 30 of the first heater 20, a leakage current flows in the chemical liquid and the magnitude of the electric current flowing through the heating wire 29 changes in comparison to the case where a tear is not formed in the coating 30. Therefore, by measuring the electric current flowing through the heating wire 29 by means of the ammeter 36 and monitoring changes in the measured electric current, a tear in the coating 30 can be detected (an abnormality of the first heater 20 can be detected). A tear in the coating 30 is detectable based on a change in a minute electric current and therefore by setting the electric current threshold, which is to be a criterion for a tear in the coating 30, to a low value (of, for example, several mA), the tear in the coating 30 can be detected with high precision and the tear in the coating 30 can be discovered at an early stage (at a stage at which the tear in the coating 30 is small). Metal contamination in the interior of the chemical liquid supplying unit 3 can thereby be prevented in advance and the chemical liquid that is free of metal contamination can be supplied from the chemical liquid supplying unit 3 to the processing unit 2. The substrate processing system 1 capable of applying a chemical liquid processing to the substrate W while avoiding the occurrence of metal contamination can thus be provided.

Also, the difference of the electric current flowing through the first portion 43 and the electric current flowing through the second portion 44 is measured by the ammeter 36 and it is judged that a tear is formed in the coating 30 if the measured value (difference in electric current) exceeds the predetermined threshold. Highly precise detection of a tear in the coating 30 can thus be performed in a simple manner. In particular, the electric currents flowing through the first and second portions 43 and 44 are measured collectively by the ammeter 36 constituted of the clamp meter and therefore influence due to error can be lessened in comparison to a case of measuring the electric currents flowing through the first and second portions 43 and 44 individually, and a tear in the coating 30 can thus be detected with even higher precision.

Also, when the formation of a tear in the coating 30 is detected, the supplying of the chemical liquid from the chemical liquid supplying unit 3 to the processing unit 2 is stopped. The chemical liquid for which there is a possibility of metal contamination is stopped from being supplied to the processing unit 2 and therefore occurrence of defective items can be suppressed to a minimum.

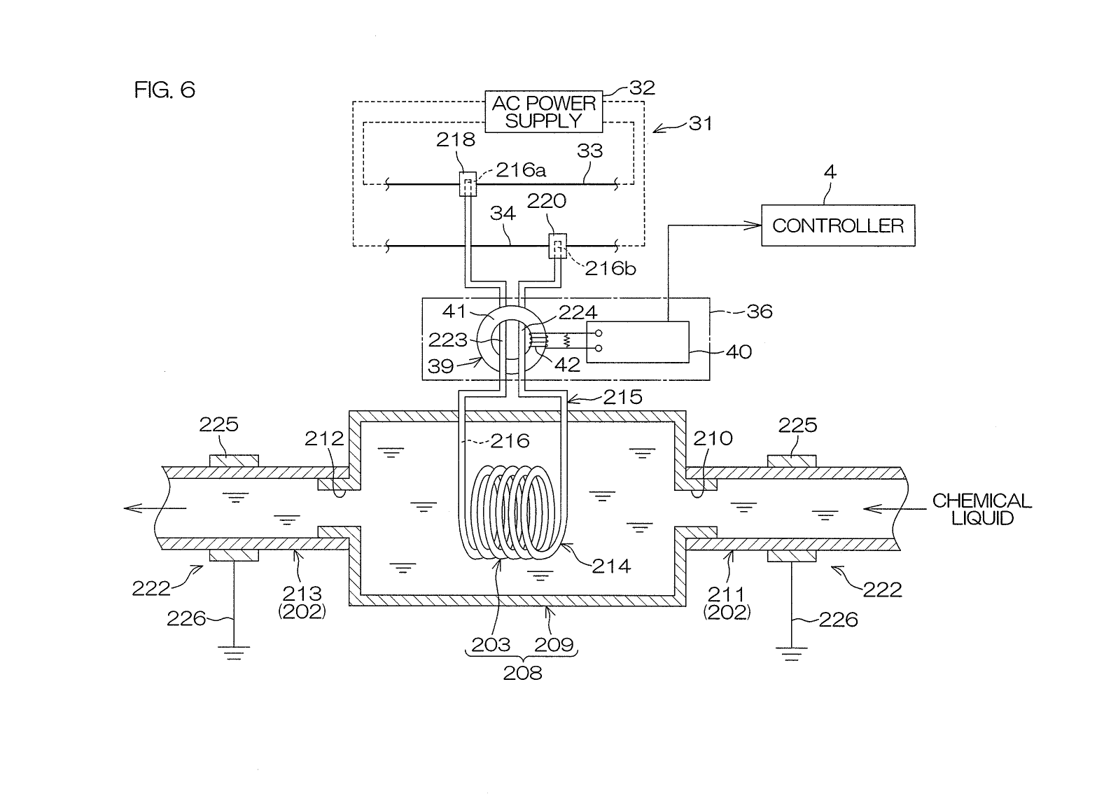

FIG. 5 is a diagram of a substrate processing system 201 according to a second preferred embodiment of the present invention as viewed in a horizontal direction. FIG. 6 is a diagram of the arrangement in a periphery of a heating unit 208 included in the substrate processing system 201 shown in FIG. 5. With the second preferred embodiment, portions corresponding to respective portions illustrated with the first preferred embodiment are indicated with the same reference symbols attached as in FIG. 1 to FIG. 4 and description thereof shall be omitted.

A point by which the substrate processing system 201 according to the second preferred embodiment differs from the substrate processing system 1 according to the first preferred embodiment is that a heater is not provided in the interior of a chemical liquid tank but a heating unit 208, including a second heater 203, is interposed in a middle portion of a chemical liquid piping (processing liquid piping) 202.

The substrate processing system 201 includes the processing unit 2, a chemical liquid supplying unit 204 as the chemical liquid supplying apparatus (processing liquid supplying apparatus) supplying a chemical liquid to the processing unit 204, and the controller 4.

The chemical liquid supplying unit 204 includes a chemical liquid tank (processing liquid tank) 205 storing the chemical liquid, the chemical liquid piping (processing liquid piping) 202 guiding the chemical liquid inside the chemical liquid tank 205 to the processing unit 2 (chemical liquid nozzle 7), the liquid feeding apparatus 17, the heating unit 208 contacting the chemical liquid flowing through the interior of the chemical liquid piping 202 and heating and performing temperature adjustment of the chemical liquid, the filter 18, the chemical liquid valve 19, the thermometer 21, the liquid volume sensor 22, the replenishing piping 23, the return piping 24, the return valve 25, and a heater abnormality detecting unit detecting an abnormality of the second heater 203 included in the heating unit 208. A heater is not immersed in the chemical liquid stored in the chemical liquid tank 205. The chemical liquid piping 202 has one end thereof connected to the chemical liquid supply piping 10 and has the other end connected to the chemical liquid tank 205. The liquid feeding apparatus 17, the heating unit 208, the filter 18, and the chemical liquid valve 19 are interposed in the chemical liquid piping 202 in that order along the chemical liquid flow direction. The chemical liquid valve 19 opens/closes the chemical liquid piping 202. The thermometer 21 measures the temperature of the chemical liquid stored in the chemical liquid tank 205. The liquid volume sensor 22 monitors the liquid volume inside the chemical liquid tank 205. The replenishing piping 23 replenishes the chemical liquid tank 205 with fresh chemical liquid. The return piping 24 connects the chemical liquid piping 202 and the chemical liquid 205 at a further downstream side in the chemical liquid flow direction than the chemical liquid valve 19. A circulation passage (flow passage) 207 that circulates the chemical liquid inside the chemical liquid tank 205 is defined by the chemical liquid tank 205, the chemical liquid piping 202, and the return piping 24.

As shown in FIG. 6, the heating unit 208 includes a circular cylindrical casing 209 and the second heater 203. An interior of the casing 209 is in communication with the interior of the chemical liquid piping 202. An inflow port 210 is disposed at an upstream side end portion in a longitudinal direction of the casing 209. A first piping (conductive piping) 211 is connected as an upstream side portion of the chemical liquid piping 202 to the inflow port 210. An outflow port 212 is disposed at a downstream side end portion in a longitudinal direction of the casing 209. A second piping (conductive piping) 213 is connected as a downstream side portion of the chemical liquid piping 202 to the outflow port 212.

As shown in FIG. 6, the second heater 203 is a sheath heater and its overall shape constitutes a shape that includes, for example, a circular annular portion 214 with ends and a pair of rectilinear portions 215 extending rectilinearly from one end portion and another end portion of the circular annular portion 214. In FIG. 6, the rectilinear portions 215 are drawn in a bent manner for the sake of description. The entirety of the circular annular portion 214 of the second heater 203 is housed in an internal space of the casing 209. Both ends of the rectilinear portions 215 are lead out to an exterior of the casing 209. As shown in FIG. 3, the sheath heater (second heater 203) includes a heating wire 216 and a coating 217. The heating wire 216 has the same arrangement as the heating wire 29 according to the first preferred embodiment. The coating 217 has the same arrangement as the coating 30 according to the first preferred embodiment. One end 216a of the heating wire 216 is connected via a third terminal 218 to the first power line 33 and another end 216b of the heating wire 216 is connected via a fourth terminal 220 to the second power line 34.

As shown in FIG. 6, the heater abnormality detecting unit includes a second grounding unit 222 that grounds the chemical liquid flowing inside the casing 209 of the heating unit 208, the ammeter 36, and the tear formation detecting unit (realized by the controller 4) that detects the formation of a tear in the coating 217 based on the magnitude of the electric current detected by the ammeter 36.

As shown in FIG. 6, a third portion 223 at the one end 216a side of the heating wire 216 and a fourth portion 224 at the other end 216b side of the heating wire 216 are measured collectively as the object of measurement by the ammeter 36. That is, both the third portion 223 and the fourth portion 224 of the heating wire 216 are surrounded by the magnetic core 41 of the ammeter 36. The electric current value determined by the calculating circuit 40 is arranged to be provided to the controller 4. By the ammeter 36 constituted from the clamp meter, the electric currents flowing through the third portion 43 and the fourth portion 224 of the heating wire 216 are measured indirectly by measuring the magnetic field due to the electric currents.

As shown in FIG. 6, the second grounding unit 222 includes cylindrical conductive bands 225, externally fitted respectively in closely-contacting states to outer peripheries of the first and second pipings 211 and 213, and second ground wires 226 connected to the conductive bands 225 and grounding the conductive bands 225.

The chemical liquid flowing through the interior of the casing 209 of the heating unit 208 is grounded by the respective conductive bands 225 and second ground wires 226 and therefore when a tear is formed in the coating 217, an electric current leaks out into the chemical liquid from the heating wire 216 that is exposed due to the tear in the coating 217 and a leakage current flows inside the chemical liquid. The magnitude of the electric current flowing through the heating wire 216 thus changes in comparison to a case where a tear is not formed in the coating 217. By measuring the electric current of the heating wire 216 by the ammeter 36, the tear in the coating 217 covering the heating wire 216 can be detected. That is, an abnormality of the second heater 203 can be detected.

The controller 4 monitors the electric current value (measured electric current value) provided from the ammeter 36. If the measured electric current value exceeds a predetermined threshold (of, for example, 1.0 mA), the controller 4 deems that a tear is formed in the coating 217 and performs an error processing. As the error processing, for example, the chemical liquid supply valve 9 is stopped. The supplying of the chemical liquid from the chemical liquid supplying unit 204 to the processing unit 2 is thereby stopped.

With the second preferred embodiment, the chemical liquid flowing through the interior of the casing 209 of the heating unit 208 is in contact with the second heater 203 and the chemical liquid is grounded via the conductive first and second pipings 211 and 213, the conductive bands 225, and the second ground wires 226. Therefore, when a tear forms in the coating 217 of the second heater 203, a leakage current flows in the chemical liquid and the magnitude of the electric current flowing through the heating wire 216 changes in comparison to the case where a tear is not formed in the coating 217. Therefore, by measuring the electric current flowing through the heating wire 216 by means of the ammeter 36 and monitoring changes in the measured electric current, a tear in the coating 217 can be detected (an abnormality of the second heater 203 can be detected). A tear in the coating 217 is detectable based on a change in a minute electric current and therefore by setting the electric current threshold, which is to be a criterion for a tear in the coating 217, to a low value (of, for example, several mA), the tear in the coating 217 can be detected with high precision and the tear in the coating 217 can be discovered at an early stage (at a stage at which the tear in the coating 217 is small). Metal contamination in the interior of the chemical liquid supplying unit 204 can thereby be prevented in advance and the chemical liquid that is free of metal contamination can be supplied from the chemical liquid supplying unit 204 to the processing unit 2. The substrate processing system 201 capable of applying a chemical liquid processing to the substrate W while avoiding the occurrence of metal contamination can thus be provided.

Also, the difference of the electric current flowing through the third portion 223 and the electric current flowing through the fourth portion 224 is measured by the ammeter 36 and it is judged that a tear is formed in the coating 217 if the measured value (difference in electric current) exceeds the predetermined threshold. Highly precise detection of a tear in the coating 217 can thus be performed in a simple manner. In particular, the electric currents flowing through the third and fourth portions 223 and 224 are measured collectively by the ammeter 36 constituted of the clamp meter and therefore influence due to error can be lessened in comparison to a case of measuring the electric currents flowing through the third and fourth portions 223 and 224 individually, and a tear in the coating 217 can thus be detected with even higher precision.

Also, when the formation of a tear in the coating 217 is detected, the supplying of the chemical liquid from the chemical liquid supplying unit 204 to the processing unit 2 is stopped. The chemical liquid for which there is a possibility of metal contamination is stopped from being supplied to the processing unit 2 and therefore occurrence of defective items can be suppressed to a minimum.

Although two preferred embodiments of the present invention were described above, the present invention may be implemented in yet other modes.

For example, although with each of the preferred embodiments described above, the arrangement where the ammeter 36 that is a clamp meter is used to measure the difference of the electric currents flowing through the first portion 43 (third portion 223) and the second portion 44 (fourth portion 224) collectively was described as an example, the electric current flowing through the first portion 43 (third portion 223) and the electric current flowing through the second portion 44 (fourth portion 224) may be measured individually and the difference of the electric currents flowing through the first portion 43 (third portion 223) and the second portion 44 (fourth portion 224) may be determined by calculation based on the measurement results.

As the ammeter 36 that is a clamp meter, besides a current transformer type, a hall element type or a flux gate type may be adopted.

Also as the ammeter 36, an ammeter other than a clamp meter may be adopted.

Also, although with each of the preferred embodiments, it was described that the AC power supply 32 outside the system is used as the AC power supply, a dedicated AC power supply arranged to supply power to the heater 20 or 203 may be disposed in the substrate processing system 1 or 201.

Also, with each of the preferred embodiments, it was described that when the formation of a tear in the coating 30 or 217 is detected, the chemical liquid supply valve 9 is stopped to stop the supply of the chemical liquid to the processing unit 2 from the chemical liquid supplying unit 3 or 204. However, when the formation of a tear in the coating 30 or 217 is detected, the controller 4 may stop the supply of electricity to the heater 20 or 203, or turn off the power supply of the chemical liquid supplying unit 3, or turn off the power supply of the entire substrate processing system 1 or 201.

Also, although with each of the preferred embodiments, it was described that the heater 20 or 203 has a shape that includes the circular annular portion 27 or 214, the heater 20 or 203 may have another form instead.

Also, although it was described that the heater 20 or 203 has the arrangement where the heating wire 29 or 216 is covered by the coating 30 or 217, for example, a periphery of a plate-shaped or rod-shaped heating element may be covered by a coating (equivalent to the coating 30 or 217) made of resin.

Also, although in each of the preferred embodiments described above, it is preferable for both the first piping 211 and the second piping 213 to be conductive pipings, it suffices that at least one of the pipings is a conductive piping. Also, portions of the chemical liquid piping 202 besides the first piping 211 and the second piping 213 may be conductive pipings or other types of pipings.

Also, the abnormality detecting apparatus according to the present invention may be applied not just to a case of heating the chemical liquid by the heater 20 or 203 but may also be applied to a case of heating water by the heater 20 or 203. In this case, water includes at least one of the pure water (deionized water), carbonated water, electrolyzed ion water, hydrogen water, ozone water, and aqueous hydrochloric acid solution of dilute concentration (for example of approximately 10 to 100 ppm).

Also, although with each of the preferred embodiments described above, the case where the substrate processing system 1 or 201 is a system that processes the disk-shaped substrate W was described, the substrate processing system 1 or 201 may instead be a system that processes a polygonal substrate, such as a substrate for liquid crystal display device, etc.

Also, although with the preferred embodiments, the substrate W was taken up as the substrate to be the processing object, the processing object is not restricted to the substrate W and may be a substrate of another type, such as a glass substrate for liquid crystal display, a substrate for plasma display, a substrate for FED, a substrate for optical disk, a substrate for magnetic disk, a substrate for magneto-optical disk, a substrate for photomask, a ceramic substrate, a substrate for solar cell, etc.

While preferred embodiments of the present invention have been described in detail above, these are merely specific examples used to clarify the technical contents of the present invention, and the present invention should not be interpreted as being limited only to these specific examples, and the scope of the present invention shall be limited only by the appended claims.

The present application corresponds to Japanese Patent Application No. 2015-37240 filed on Feb. 26, 2015 in the Japan Patent Office, and the entire disclosure of this application is incorporated herein by reference.

1. A heater abnormality detecting apparatus arranged to detect an abnormality of a heater, the heater contacting a processing liquid to heat the processing liquid and having a heating element made of metal and a coating made of resin and covering a periphery of the heating element, the apparatus comprising:
a grounding unit grounding the processing liquid in contact with the heater;
a power supplying unit supplying power to the heating element to make the heating element generate heat;
an electric current measuring unit measuring an electric current flowing through the heating element; and
a tear formation detecting unit detecting formation of a tear in the coating based on a magnitude of the electric current detected by the electric current measuring unit.

2. The heater abnormality detecting apparatus according to claim 1, wherein the power supplying unit includes a first power line connected to an AC power supply and a second power line connected to the AC power supply and being different from the first power line,
the heating element includes a heating wire with ends, one end of the heating wire is connected to the first power line, the other end of the heating wire is connected to the second power line, and
the electric current measuring unit includes an electric current difference measuring unit measuring a difference of an electric current flowing through a first portion at the one end side of the heating wire and an electric current flowing through a second portion at the other end side of the heating wire.

3. The heater abnormality detecting apparatus according to claim 2, wherein the electric current difference measuring unit includes a clamp meter.

4. The heater abnormality detecting apparatus according to claim 3, wherein the electric currents flowing through the first portion and the second portion are measured collectively by the clamp meter.

5. A processing liquid supplying apparatus arranged to supply a processing liquid to a processing portion arranged to apply processing by the processing liquid to a processing object, the processing liquid supplying apparatus comprising:
a flow passage, through which the processing liquid flows;
a heater arranged to contact the processing liquid present in an interior of the flow passage and heat the processing liquid, the heater including a heating element made of metal and a coating made of resin and covering a periphery of the heating element; and
a heater abnormality detecting apparatus arranged to detect an abnormality of a heater, the heater contacting a processing liquid to heat the processing liquid and having a heating element made of metal and a coating made of resin and covering a periphery of the heating element, the apparatus comprising,
a grounding unit grounding the processing liquid in contact with the heater,
a power supplying unit supplying power to the heating element to make the heating element generate heat,
an electric current measuring unit measuring an electric current flowing through the heating element, and
a tear formation detecting unit detecting formation of a tear in the coating based on a magnitude of the electric current detected by the electric current measuring unit.

6. The processing liquid supplying apparatus according to claim 5, wherein the flow passage includes a processing liquid tank storing the processing liquid to be supplied to the processing portion and a processing liquid piping guiding the processing liquid from the processing liquid tank to the processing portion,
the heater includes a first heater immersed in the processing liquid stored in the processing liquid tank and heating the processing liquid, and
the grounding unit includes a first grounding unit grounding the processing liquid stored in the processing liquid tank.

7. The processing liquid supplying apparatus according to claim 6, wherein the first grounding unit includes
a conductive member disposed so as to contact the processing liquid stored in the processing liquid tank and a first ground wire arranged to ground the conductive member.

8. The processing liquid supplying apparatus according to claim 5, wherein the flow passage includes a processing liquid tank storing the processing liquid to be supplied to the processing portion and a processing liquid piping guiding the processing liquid from the processing liquid tank to the processing portion,
the heater includes a second heater interposed in the processing liquid piping and heating the processing liquid flowing through the processing liquid piping, and
the grounding unit includes a second grounding unit grounding the processing liquid flowing through the processing liquid piping.

9. The processing liquid supplying apparatus according to claim 8, wherein with the processing liquid piping, at least a portion connected to the second heater is disposed as a conductive piping formed using a material having conductivity, and
the second grounding unit includes a second ground wire arranged to ground the conductive piping.

10. A substrate processing system comprising:
a processing portion arranged to apply processing by a processing liquid to a processing object; and
a processing liquid supplying apparatus arranged to supply a processing liquid to a processing portion arranged to apply processing by the processing liquid to a processing object, the processing liquid supplying apparatus comprising,
a flow passage, through which the processing liquid flows,
a heater arranged to contact the processing liquid present in an interior of the flow passage and heat the processing liquid, the heater including a heating element made of metal and a coating made of resin and covering a periphery of the heating element, and
a heater abnormality detecting apparatus arranged to detect an abnormality of a heater, the heater contacting a processing liquid to heat the processing liquid and having a heating element made of metal and a coating made of resin and covering a periphery of the heating element, the apparatus comprising a grounding unit grounding the processing liquid in contact with the heater, a power supplying unit supplying power to the heating element to make the heating element generate heat, an electric current measuring unit measuring an electric current flowing through the heating element, and a tear formation detecting unit detecting formation of a tear in the coating based on a magnitude of the electric current detected by the electric current measuring unit; and
supplying a processing liquid, supplied from the processing liquid supplying apparatus, to a substrate inside the processing portion to process the substrate.

11. The substrate processing system according to claim 10, wherein the supplying of the processing liquid from the processing liquid supplying apparatus to the substrate is stopped when the tear formation detecting unit detects the formation of a tear in the coating.
